(19) United States
(12) Patent Application Publication
(10) Pub. No.: US 2024/0107249 A1
(43) Pub. Date: Mar. 28, 2024

(54) MOLDED INTEGRATED CIRCUIT PACKAGE WITH SENSOR ASSEMBLY

(71) Applicant: Apple Inc., Cupertino, CA (US)

(72) Inventors: Kyusang KIM, Singapore (SG); Ali N. Ergun, Sunnyvale, CA (US); Anthony D. Minervini, Gilroy, CA (US); Bilal Mohamed Ibrahim Kani, Singapore (SG); Kishore N. Renjan, Singapore (SG)

(73) Assignee: Apple Inc., Cupertino, CA (US)

(21) Appl. No.: 18/119,600

(22) Filed: Mar. 9, 2023

Related U.S. Application Data
(60) Provisional application No. 63/409,556, filed on Sep. 23, 2022.

(51) Int. Cl. H04R 31/00; H04R 1/04

(52) U.S. Cl. CPC H04R 31/00; H04R 1/04

(57) ABSTRACT

Embodiments of the present disclosure include a structure with a substrate, an electronic device, and a molding compound layer. The substrate has a first surface and a second surface opposite to the first surface, where the substrate includes a first opening. The electronic device is disposed on the first surface of the substrate and includes a second opening aligned with the first opening of the substrate. Further, the molding compound layer is disposed on the second surface of the substrate and includes a third opening aligned with the second opening of the electronic device.

### REFERENCE TO RELATED APPLICATION

This application claims the benefit of U.S. Provisional Patent Application No. 63/409,556, titled “Electronic Circuit Package with Mold Opening,” filed on Sep. 23, 2022, the disclosure of which is incorporated by reference herein in its entirety.

### FIELD

This disclosure relates to an electronic circuit package and, more particularly, to an electronic circuit package with a mold opening.

### BACKGROUND

An electronic circuit package can include active devices, passive devices, and/or integrated circuits, which are mounted on a printed circuit board (PCB) and electrically connected to one another through conductive traces in a PCB substrate. PCBs can be classified into three categories based on their flexibility—e.g., rigid PCBs, flexible PCBs, and rigid-flex PCBs. Rigid PCBs include a rigid substrate that cannot be bent or forced out of shape. Once manufactured, rigid PCBs cannot be modified or folded into any other shape. Flexible PCBs can include a flexible substrate that can be folded. Flexible PCBs can be made of a flexible plastic material. Rigid-flex PCBs can include both rigid and flexible substrates, where a first region of the PCB is rigid and a second region of the PCB is flexible.

Space, height, and design constraints of the electronic circuit package can determine the type of PCB used in the package. For example, these constraints can be based on a form factor of an electronic system incorporating the electronic circuit package, such as a mobile phone, a wearable device, a portable gaming device, and other types of electronic devices.

### SUMMARY

Embodiments of the present disclosure include a structure with a substrate, an electronic device, and a molding compound layer. The substrate has a first surface and a second surface opposite to the first surface, where the substrate includes a first opening. The electronic device is disposed on the first surface of the substrate and includes a second opening aligned with the first opening of the substrate. Further, the molding compound layer is disposed on the second surface of the substrate and includes a third opening aligned with the second opening of the electronic device.

Embodiments of the present disclosure include another structure with a printed circuit board (PCB), a first molding compound layer, a microphone device, and a second molding compound layer. The PCB has a first surface and a second surface opposite to the first surface, where the PCB includes a PCB opening. The first molding compound layer is disposed on the first surface of the PCB and includes a sound guide opening aligned with the PCB opening. The microphone device is disposed on the second surface of the PCB and includes a sound inlet opening aligned with the PCB opening and the sound guide opening. The second molding compound layer is disposed on the second surface of the PCB and surrounds the microphone device.

Embodiments of the present disclosure also include a method for packaging an electronic device with a mold opening. The method includes the following operations: attaching an electronic device to a first surface of a substrate and over a first opening in the substrate, where the electronic device includes a second opening aligned with the first opening in the substrate; forming a first molding compound layer over the first surface of the substrate and to surround the electronic device; and forming, over a second surface of the substrate, a second molding compound layer with a third opening aligned with the first opening of the substrate and the second opening of the electronic device.

Embodiments of the present disclosure further include a method for packaging an electronic device with multiple mold openings. The method includes the following operations: attaching an electronic device to a first surface of a substrate and over a first opening in the substrate, where the electronic device includes a second opening aligned with the first opening in the substrate and a third opening on a surface of the electronic device opposite to that of the second opening; forming a first molding compound layer over the first surface of the substrate and to surround the electronic device, where the first molding compound layer includes a fourth opening aligned with the third opening of the electronic device; and forming, over a second surface of the substrate, a second molding compound layer with a fifth opening aligned with the first opening of the substrate and the second opening of the electronic device.

### BRIEF DESCRIPTION OF THE DRAWINGS

Aspects of this disclosure are best understood from the following detailed description when read with the accompanying figures.

FIG. 1 is a cross-sectional view of an electronic circuit package with multiple mold openings, according to some embodiments.

FIG. 2 is another cross-sectional view of an electronic circuit package with multiple mold opening, according to some embodiments.

FIG. 3 is yet another cross-sectional view of an electronic circuit package with multiple mold openings, according to some embodiments.

FIG. 4 is a flow diagram of a method for packaging an electronic device with a mold opening, according to some embodiments.

FIGS. 5-15 are cross-sectional views of electronic circuit packages with a mold opening at various stages of their packaging process, according to some embodiments.

FIG. 16 is a flow diagram of a method for packaging an electronic device with multiple mold openings, according to some embodiments.

FIGS. 17-23 are cross-sectional views of electronic circuit packages with multiple mold openings at various stages of their packaging process, according to some embodiments.

FIG. 24 illustrates exemplary systems or devices that can include the disclosed electronic circuit packages with molding openings, according to some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The present disclosure describes structures and methods directed to an electronic circuit package with a mold opening. For example, a structure can include a substrate with an opening, an electronic device disposed on a first surface of the substrate, and a molding compound layer disposed on a second surface of the substrate. The electronic device can include an opening aligned with the substrate's opening. Further, the molding compound layer can include an opening aligned with the electronic device and the substrate's openings. Depending on the type of operation of the electronic device (e.g., electronic sensor device), the electronic device can receive and/or transmit signals—e.g., sound waves, optical signals, pressure signals, communication signals, and light-emitting signals—through the openings of the electronic device, substrate, and molding compound layer and process the signals accordingly.

Benefits of the above electronic circuit package, among others, include a miniaturized design with volumetric efficiency as compared to other electronic circuit packages with the electronic device and associated openings that deliver signals to the electronic device not in close proximity to one another. Another benefit of the above electronic circuit package is manufacturing simplicity, resulting in reduced manufacturing costs. For example, for the above electronic circuit package, the electronic device and molding compound layer can be manufactured on the same type of substrate—e.g., a rigid PCB—such that the manufacturing process does not need to be modified to integrate the electronic device on a different type of substrate—e.g., a flexible PCB—from other electronic components in the electronic system.

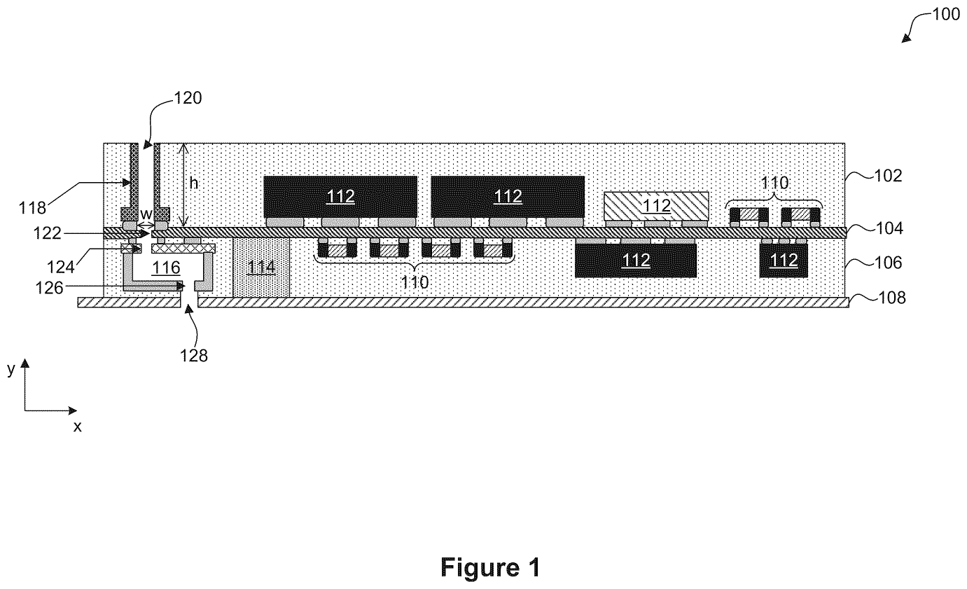

FIG. 1 is a cross-sectional view of an electronic circuit package 100 with openings 120 and 128, according to some embodiments. Electronic circuit package 100 includes a molding compound layer 102, a substrate 104, a molding compound layer 106, and a substrate 108. Molding compound layer 102 and molding compound layer 106 are disposed on opposite surfaces—e.g., top and bottom surfaces—of substrate 104. Further, substrate 108 is in contact with molding compound layer 106.

In some embodiments, substrate 104 can be a PCB, such as a rigid PCB, with one or more electronic devices disposed on a first surface (e.g., top surface) or both first and second surfaces (e.g., top and bottom surfaces) of substrate 104. The electronic devices can include one or more passive devices 110, one or more integrated circuit (IC) chips 112, an interposer structure 114, and an electronic device 116. The one or more passive devices 110 can include resistors, capacitors, inductors, or any combination thereof. The one or more IC chips 112 can include any suitable type of IC chip to support one or more functions of an electronic system incorporating electronic circuit package 100, such as wireless communication, battery charging, touch and/or acoustic sensing, and other types of functions.

In some embodiments, substrate 104 includes an opening 122 (also referred to herein as “substrate opening 122” and “PCB opening 122”). Electronic device 116 can be disposed on a surface (e.g., bottom surface) of substrate 104 so that a first opening 124 of electronic device 116 aligns with opening 122 of substrate 104. Molding compound layer 102 is disposed on another surface (e.g., top surface) of substrate 104 and includes opening 120 (also referred to herein as “mold opening 120” and “mold cavity 120”) aligned with opening 122 of substrate 104 and first opening 124 of electronic device 116. In some embodiments, opening 120 can have substantially vertical sidewalls (e.g., in the y-direction), a height dimension h between about 100 μm and 2.0 cm, and a bottom width dimension w between about 200 μm and about 1000 μm. In some embodiments, a guide structure 118 can be disposed along the substantially vertical sidewalls of opening 120. Guide structure 118 can include two L-shaped structures—with each L-shaped structure disposed along a sidewall of opening 120—made of a metallic material or any other suitable material. In some embodiments, a mid-section portion of the L-shaped structure (e.g., mid-section of the long vertical portion of the “L” shape) can have a thickness between about 400 μm and about 600 μm.

Electronic device 116 can also include a second opening 126. Molding compound layer 106 is disposed on a surface (e.g., bottom surface) of substrate 104. Substrate 108 is in contact with molding compound layer 106. Substrate 108 can be a PCB, such as a flexible PCB, and can electrically connect other electronic components (not shown in FIG. 1) to electronic circuit package 100 through interposer structure 114, which is electrically connected to substrate 104 and substrate 108. In some embodiments, opening 128 (also referred to herein as “mold opening 128” and “mold cavity 128”) is formed through molding compound layer 106 and substrate 108 so that second opening 126 of electronic device 116 aligns with opening 128.

In some embodiments, electronic device 116 can be an electronic sensor device, such as a microphone device, an optical sensor device, and a pressure sensing device. For a microphone device 116, opening 120 in molding compound layer 102 can function as a sound guide opening to receive and transfer sound waves to first opening 124 (e.g., a sound inlet opening) of microphone device 116. Guide structure 118 can be a sound guide structure to help direct the sound waves to first opening 124 of microphone device 116. Further, opening 128 in molding compound layer 106 and substrate 108 can function as barometric relief opening to, for example, equalize pressure that may build up in microphone device 116. Second opening 126 of microphone device 116 (e.g., a barometric relief vent) can be used to equalize the pressure. As shown in FIG. 1, second opening 126 (e.g., a barometric relief vent) is on a surface of microphone device 116 opposite to that of first opening 124 (e.g., a sound inlet opening). Based on the description herein, one or both openings 120 and 128 in electronic circuit package 100 can be used for other types of applications—e.g., an optical sensing application, a pressure sensing application, a communication application (e.g., receiving and/or transmitting communication signals), and a light-emitting application—depending on the function and design of electronic device 116. Further based on the application of electronic circuit package 100, the dimensions of openings 120 and 128 (e.g., dimensions h and w) can vary.

In some embodiments, one or more of passive devices 110, IC chips 112, interposer structure 114, electronic device 116, and guide structure 118 are disposed on substrate 104 using a surface-mount process. Further, the one or more passive devices 110, the one or more IC chips 112, interposer structure 114, and electronic device 116 can electrically connect to one another through conductive traces in substrate 104. Other electrical component placement and routing techniques can also be used for one or more of these electrical components. Further, the number and arrangement of the one or more passive devices 110, the one or more IC chips 112, interposer structure 114, and electronic device 116 can vary based on the application of electronic circuit package 100. Other numbers and arrangements of electrical components are within the scope of the present disclosure.

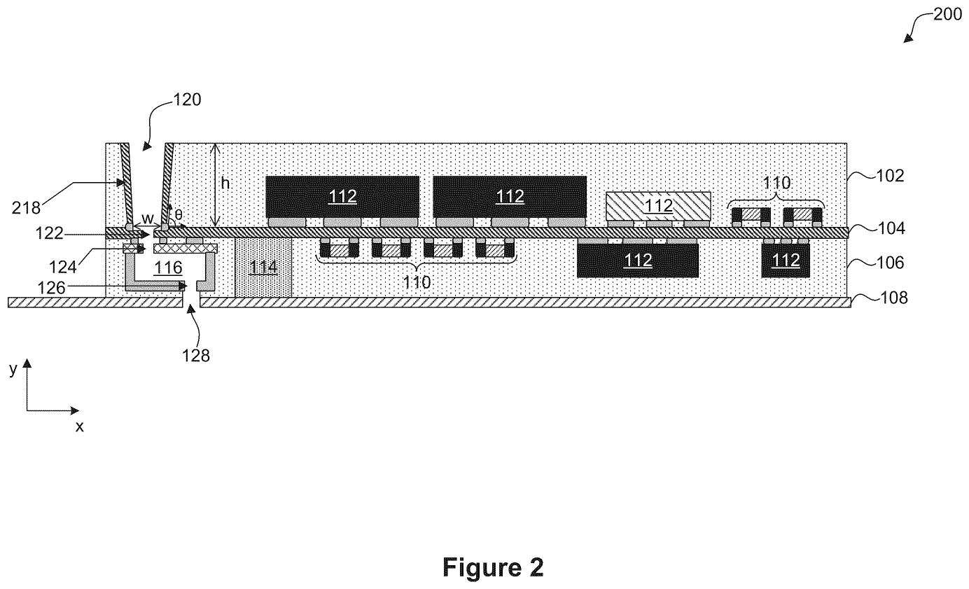

FIG. 2 is another cross-sectional view of an electronic circuit package 200 with openings 120 and 128, according to some embodiments. The discussion of elements in electronic circuit package 100 of FIG. 1 and electronic circuit package 200 of FIG. 2 with the same annotations applies to each other, unless mentioned otherwise.

In some embodiments, opening 120 in molding compound layer 102 has angled sidewalls (e.g., relative to the x-direction) with a guide structure 218 disposed along the angled sidewalls. With angled sidewalls, opening 120 can have a wider top opening as compared to a bottom opening. Guide structure 218 can be a barrier layer made of a metallic material or any other suitable material. The barrier layer can have a thickness between about 80 μm and about 120 μm.

Further, in some embodiments, a sidewall angle θ can depend on the function and design of electronic device 116. For example, if electronic device 116 is a microphone device, opening 120 in molding compound layer 102 can function as a sound guide opening to receive and transfer sound waves to first opening 124 (e.g., a sound inlet opening) of microphone device 116. Guide structure 218 can be a sound guide structure to help direct the sound waves to first opening 124 of microphone device 116. To optimize the direction of the sound waves to first opening 124, the sidewall angle θ can be adjusted. Based on the description herein, the sidewall angle θ can be adjusted based on other types of applications—e.g., an optical sensing application, a pressure sensing application, a communication application (e.g., receiving and/or transmitting communication signals), and a light-emitting application. Further based on the application of electronic circuit package 200, the dimensions of openings 120 and 128 (e.g., dimensions h and w and sidewall angle θ) can vary.

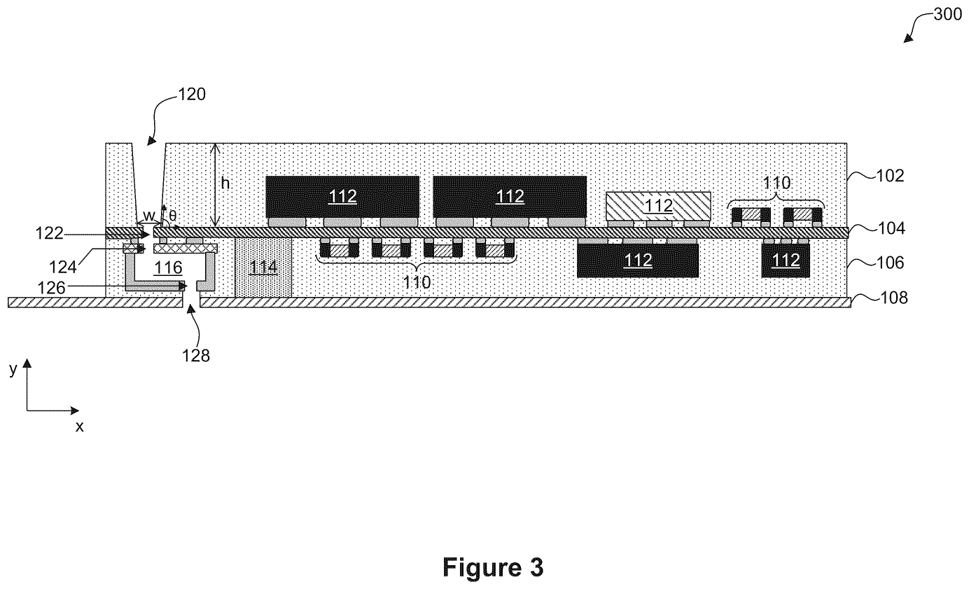

FIG. 3 is yet another cross-sectional view of an electronic circuit package 300 with openings 120 and 128, according to some embodiments. The discussion of elements in electronic circuit package 100 of FIG. 1, electronic circuit package 200 of FIG. 2, and electronic circuit package 300 of FIG. 3 with the same annotations applies to each other, unless mentioned otherwise.

Unlike electronic circuit package 100 of FIG. 1 and electronic circuit package 200 of FIG. 2, the sidewalls of opening 120 in molding compound layer 102 do not include a guide structure (e.g., guide structure 118 of FIG. 1 and guide structure 218 of FIG. 2). But similar to electronic circuit package 100 and electronic circuit package 200, based on the application of electronic circuit package 300, the dimensions of openings 120 and 128 (e.g., dimensions h and w and sidewall angle θ) can vary.

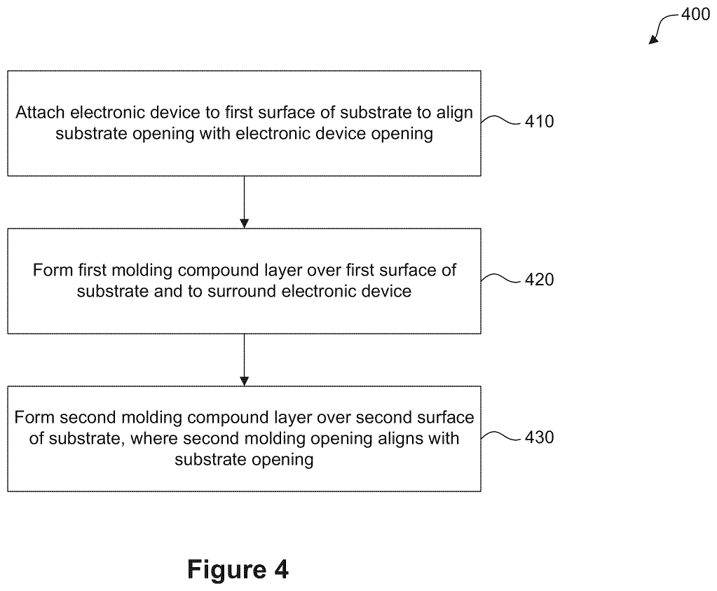

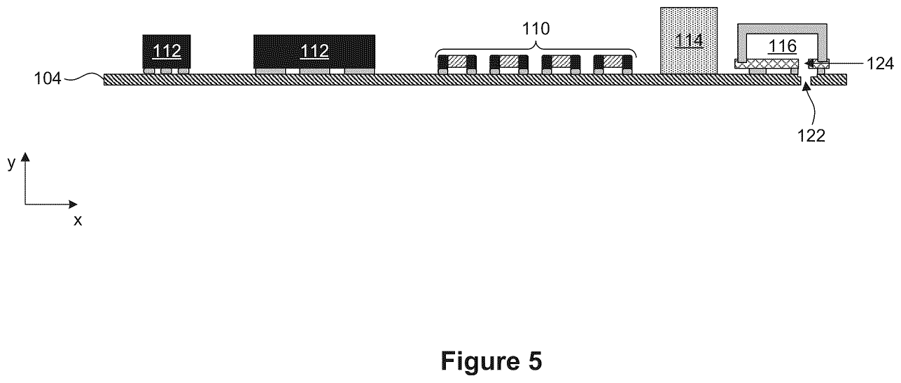

FIG. 4 is a flow diagram of a method 400 for packaging an electronic device with opening 120, according to some embodiments. For illustrative purposes, the operations of method 400 will be described with reference to FIGS. 5-15, which are cross-sectional views of electronic circuit packages—including an electronic circuit package with guide structure 118, an electronic circuit package with guide structure 218, and an electronic circuit package with no guide structure—at various stages of their packaging process, according to some embodiments. Elements in FIGS. 5-15 with the same annotations as elements in FIGS. 1-3 are described above.

The operations of method 400 can be performed in a different order or not performed depending on specific applications. It should be noted that method 400 may not produce a complete electronic circuit package. Accordingly, it is understood that additional operations can be provided before, during, and after method 400, and that some other operations may only be briefly described herein.

Referring to FIG. 4, in operation 410, an electronic device is attached to a first surface of a substrate and over a first opening in the substrate. The electronic device includes a second opening aligned with the first opening in the substrate. Referring to FIG. 5, electronic device 116 is attached to substrate 104 and over opening 122 in substrate 104. Electronic device 116 includes opening 124 aligned with opening 122 in substrate 104. In some embodiments, electronic device 116 can be attached to substrate 104 using a surface-mount process, where electronic device 116 is attached to substrate 104 so that openings 122 and 124 are aligned and then electrical contacts of electronic device 116 are soldered to conductive traces on substrate 104. In some embodiments, the solder can surround a spacing between opening 124 of electronic device 116 and opening 122 in substrate 104 such that the openings are not filled during a subsequent molding process (e.g., operation 420 below). One or more passive devices 110, one or more IC chips 112, and interposer structure 114 can also be attached to substrate 104 using the surface-mount process. Other electrical component placement and routing techniques can also be used for one or more of these electrical components.

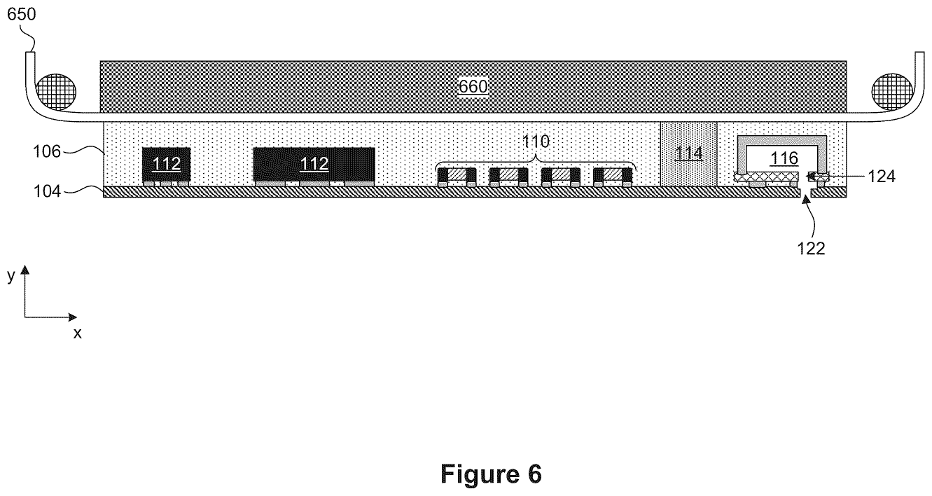

Referring to FIG. 4, in operation 420, a first molding compound layer is formed over the first surface of the substrate and to surround the electronic device. Referring to FIG. 6, in some embodiments, a film-assisted molding process can be used to form molding compound layer 106 over the surface of substrate 104 and to surround electronic device 116. During the film-assisted molding process, a film 650 can be positioned and vacuum sealed along a surface of a chase 660 of a molding tool. After substrate 104 (with electrical components attached thereon) is transferred to the molding tool, film 650 is in contact with a surface (e.g., top surface) of interposer structure 114 so that, during a molding encapsulation process, molding compound layer 106 is formed around interposer structure 114 and surrounds the one or more passive devices 110, the one or more IC chips 112, and electronic device 116. In some embodiments, molding compound layer 106 can be a polymeric molding compound or any other suitable material.

Referring to FIG. 4, in operation 430, a second molding compound layer is formed over a second surface of the substrate. The second molding compound layer includes a third opening aligned with the first opening of the substrate and the second opening of the electronic device.

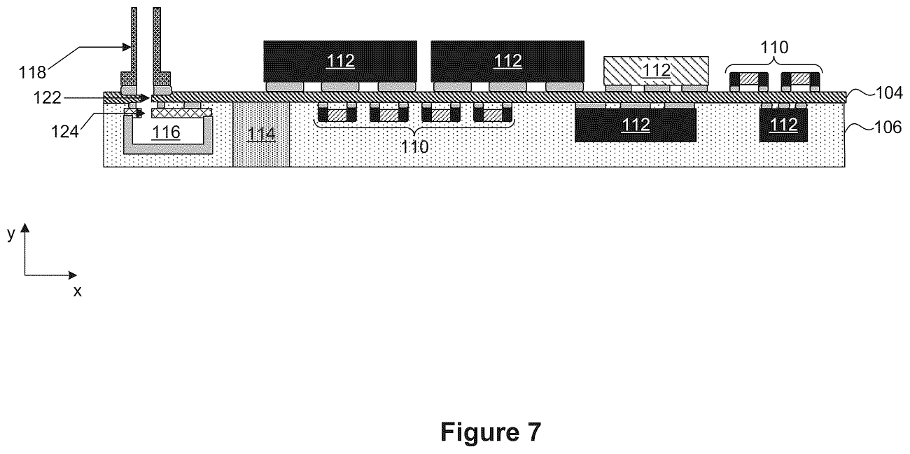

Referring to FIG. 7, for the electronic circuit package with guide structure 118 and prior to forming molding compound layer 102, guide structure 118 can be attached to a surface of substrate 104 opposite to that of electronic device 116. Guide structure 118 can include two L-shaped structures made of a metallic material or any other suitable material. Guide structure 118 can be attached to substrate 104, at a substantially vertical orientation (e.g., in the y-direction), using a surface-mount process, according to some embodiments. Further, one or more passive devices 110 and one or more IC chips 112 can be attached to the same surface of substrate 104 as guide structure using the surface-mount process.

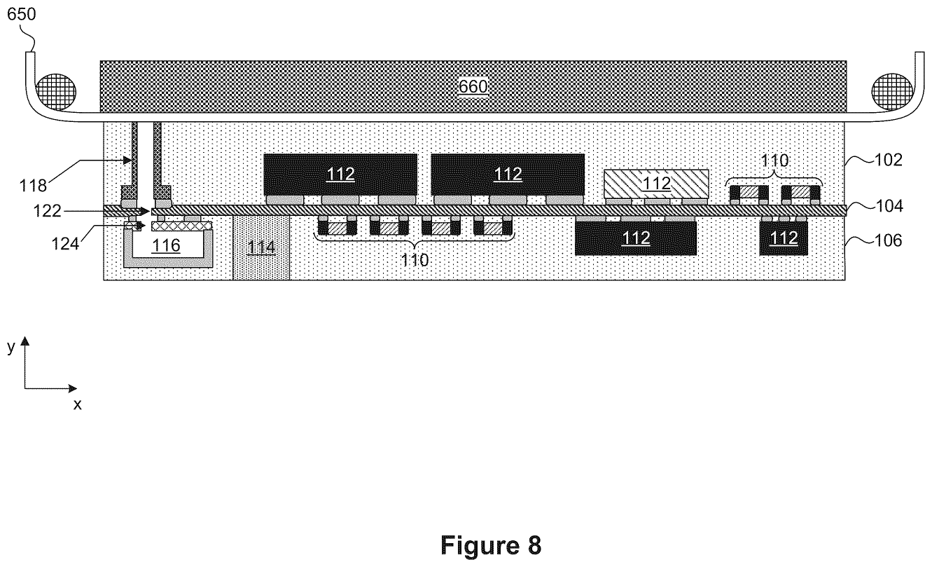

Referring to FIG. 8, for the electronic circuit package with guide structure 118, molding compound layer 102 is formed over the surface of substrate 104 with guide structure 118. In some embodiments, a film-assisted molding process can be used to form molding compound layer 102. After substrate 104 (with electrical components attached thereon) is transferred to the molding tool, film 650 is in contact with a surface (e.g., top surface) of guide structure 118 so that, during a molding encapsulation process, molding compound layer 102 is formed around guide structure 118 and surrounds the one or more passive devices 110 and the one or more IC chips 112.

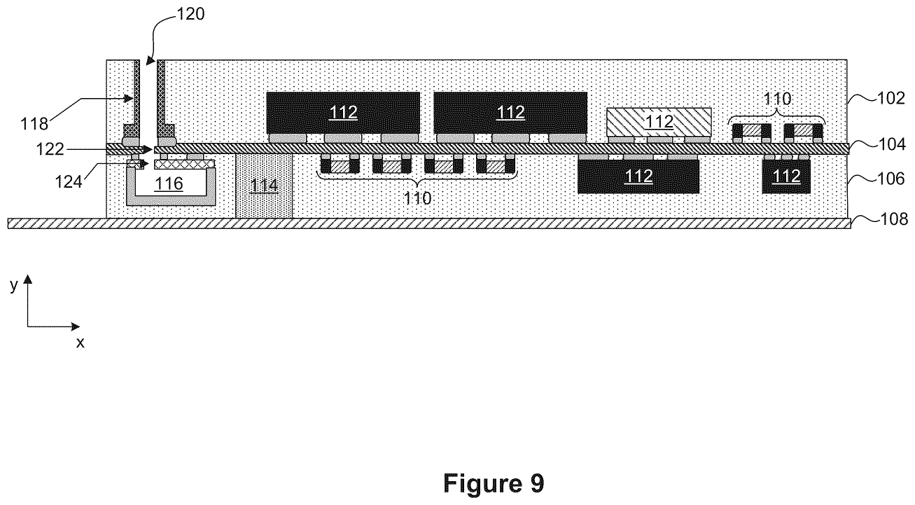

After molding compound layer 102 is formed, substrate 108 can be attached to molding compound layer 106. FIG. 9 shows the electronic circuit package with substrate 108, guide structure 118, and opening 120 in molding compound layer 102, according to some embodiments.

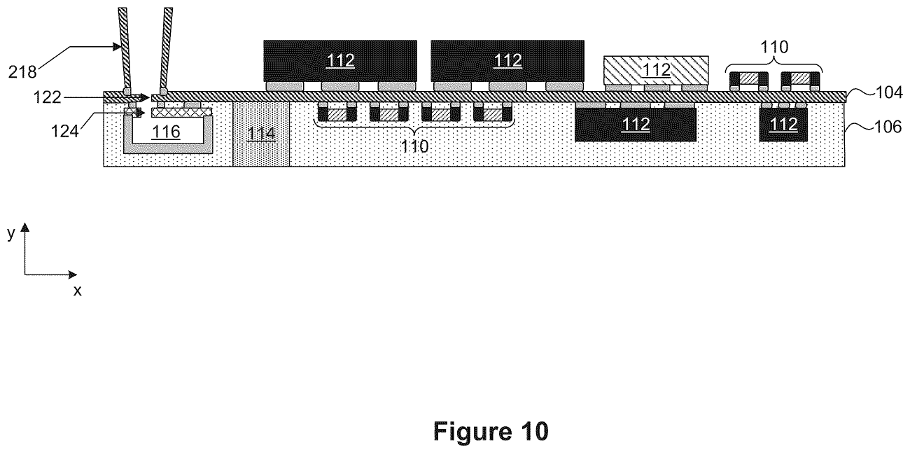

Referring to FIG. 10, for the electronic circuit package with guide structure 218 and prior to forming molding compound layer 102, guide structure 218 can be attached to a surface of substrate 104 opposite to that of electronic device 116. Guide structure 218 can be made of a metallic material or any other suitable material and can be attached to substrate 104, at an angled orientation (e.g., relative to the x-direction), using a surface-mount process, according to some embodiments. Further, one or more passive devices 110 and one or more IC chips 112 can be attached to the same surface of substrate 104 as guide structure using the surface-mount process.

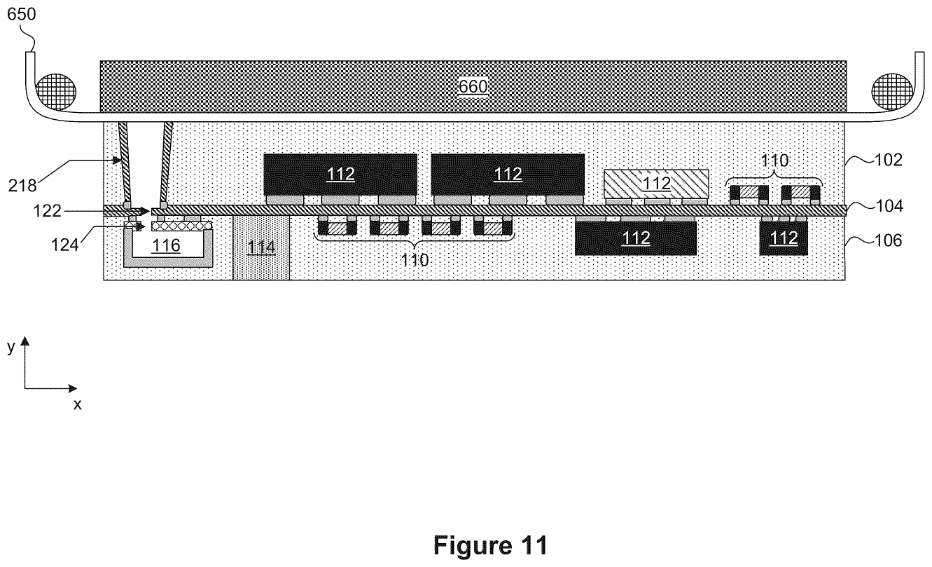

Referring to FIG. 11, for the electronic circuit package with guide structure 218, molding compound layer 102 is formed over the surface of substrate 104 with guide structure 218. In some embodiments, a film-assisted molding process can be used to form molding compound layer 102. After substrate 104 (with electrical components attached thereon) is transferred to a molding tool, film 650 is in contact with a surface (e.g., top surface) of guide structure 218 so that, during a molding encapsulation process, molding compound layer 102 is formed around guide structure 218 and surrounds the one or more passive devices 110 and the one or more IC chips 112.

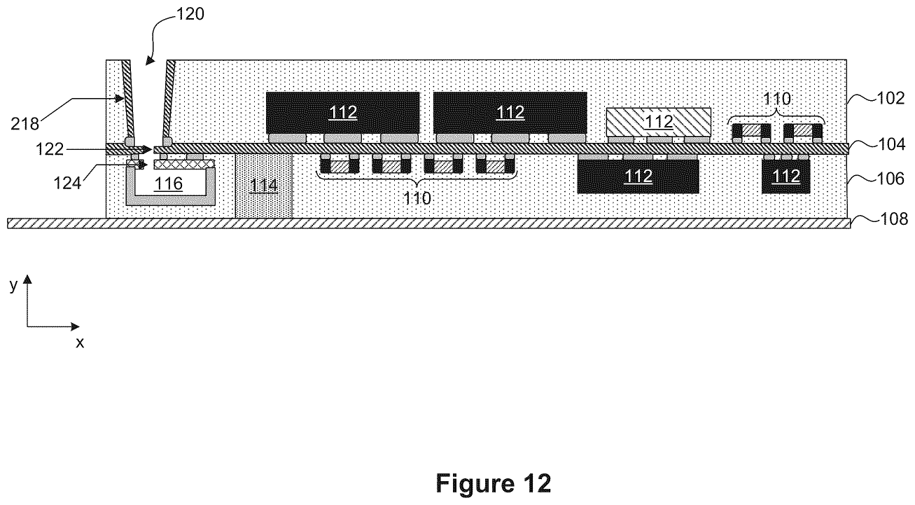

After molding compound layer 102 is formed, substrate 108 can be attached to molding compound layer 106. FIG. 12 shows the electronic circuit package with substrate 108, guide structure 218, and opening 120 in molding compound layer 102, according to some embodiments.

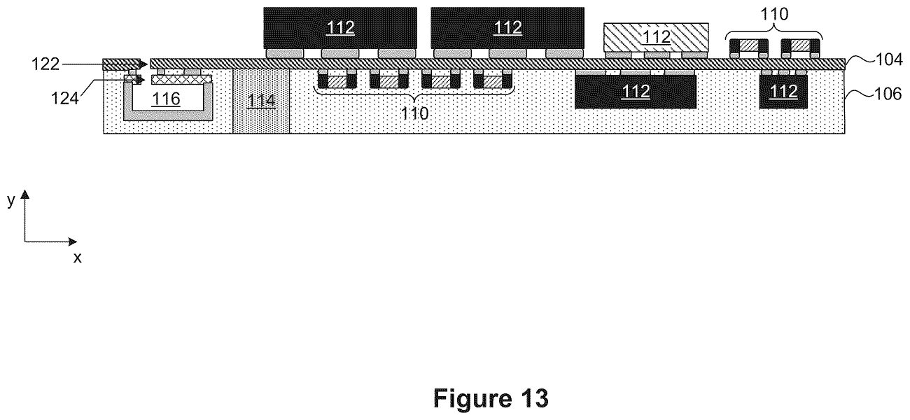

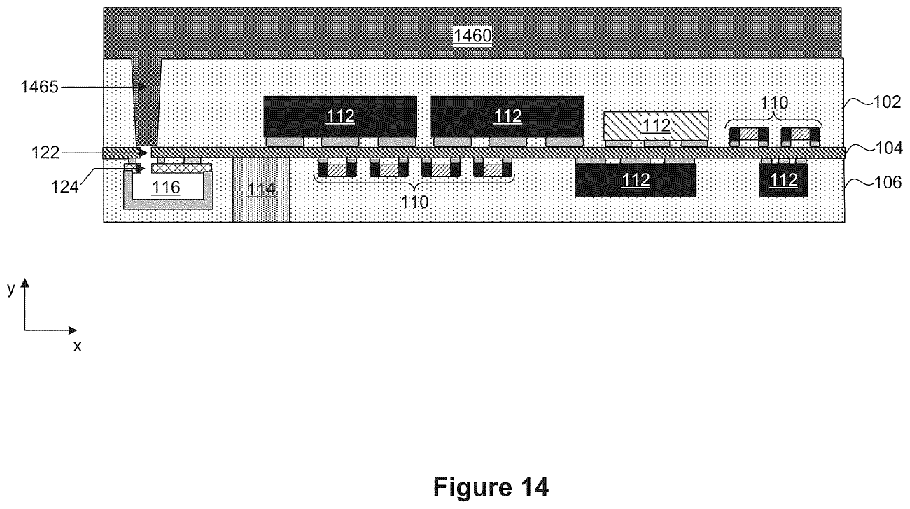

Referring to FIG. 13, for the electronic circuit package with no guide structure, molding compound layer 102 is formed over the surface of substrate 104. Referring to FIG. 14, in some embodiments, a chase 1460 of a molding tool can include an insert portion 1465 that lands on opening 122 in substrate 104 during a molding encapsulation process. During the molding encapsulation process, molding compound layer 102 is formed around insert portion 1465 and surrounds the one or more passive devices 110 and the one or more IC chips 112.

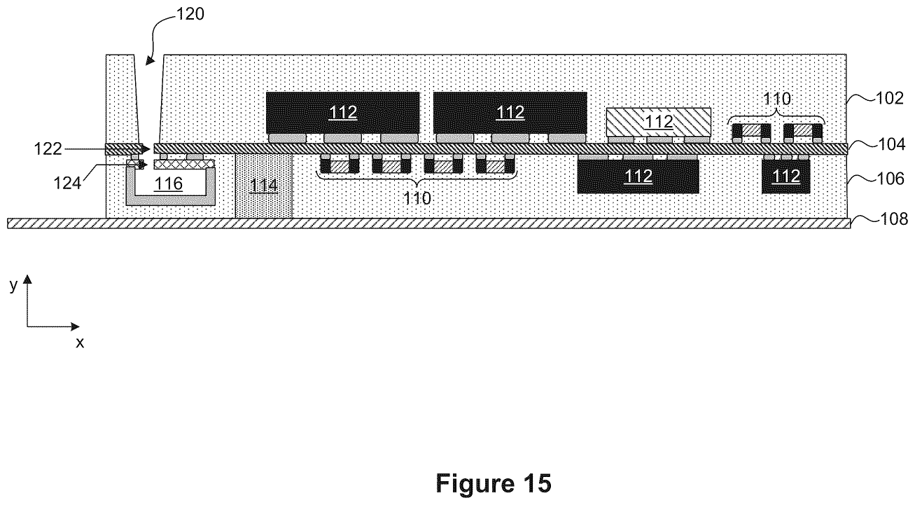

After molding compound layer 102 is formed, substrate 108 can be attached to molding compound layer 106. FIG. 15 shows the electronic circuit package with substrate 108 and with no guide structure in opening 120 of molding compound layer 102, according to some embodiments.

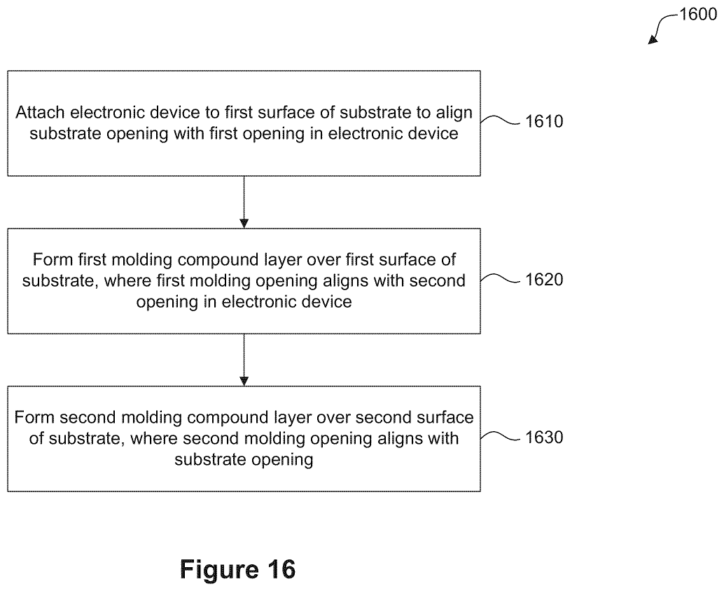

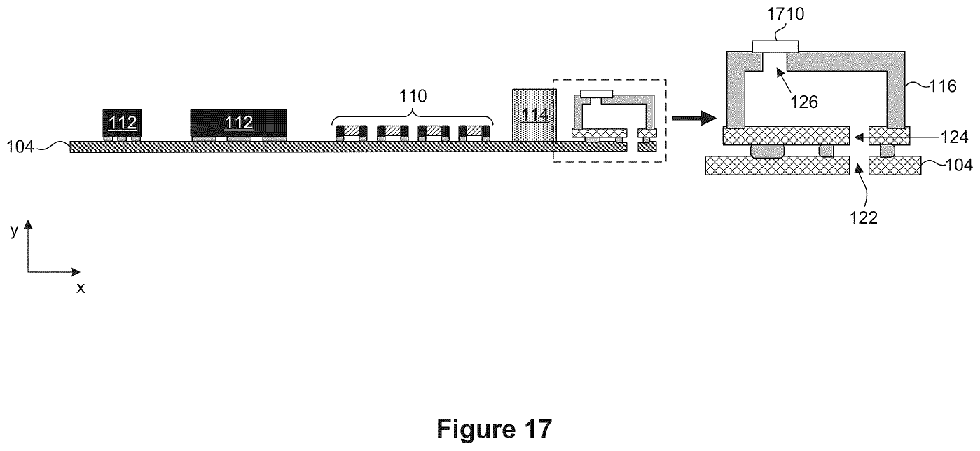

FIG. 16 is a flow diagram of a method 1600 for packaging an electronic device with openings 120 and 128, according to some embodiments. For illustrative purposes, the operations of method 1600 will be described with reference to FIGS. 17-23, which are cross-sectional views of electronic circuit package 100 at various stages of its packaging process, according to some embodiments. Elements in FIGS. 17-23 with the same annotations as elements in FIG. 1 are described above.

In some embodiments, method 1600 include operations to manufacture electronic circuit package 100 while covering opening 126 and to manufacture electronic circuit package 100 without covering opening 126. The operations of method 1600 can be performed in a different order or not performed depending on specific applications. It should be noted that method 1600 may not produce a complete electronic circuit package. Accordingly, it is understood that additional operations can be provided before, during, and after method 1600, and that some other operations may only be briefly described herein. Though the operations of method 1600 are described below in the context of forming opening 128 in electronic circuit package 100 of FIG. 1, these operations are equally applicable to forming opening 128 in electronic circuit package 200 of FIG. 2 and electronic circuit package 300 of FIG. 3.

Referring to FIG. 16, in operation 1610, an electronic device is attached to a first surface of a substrate and over a first opening in the substrate. The electronic device includes a second opening aligned with the first opening in the substrate and a third opening on a surface of the electronic device opposite to that of the second opening.

Referring to FIG. 17, for the manufacturing of electronic circuit package 100 while covering opening 126, electronic device 116 is attached to substrate 104 and over opening 122 in substrate 104. Electronic device 116 includes opening 124 aligned with opening 122 in substrate 104. In some embodiments, electronic device 116 can be attached to substrate 104 using a surface-mount process, where electronic device 116 is attached to substrate 104 so that openings 122 and 124 are aligned and then electrical contacts of electronic device 116 are soldered to conductive traces on substrate 104. In some embodiments, the solder can surround a spacing between opening 124 of electronic device 116 and opening 122 in substrate 104 such that the openings are not filled during a subsequent molding process (e.g., operation 1620 below). One or more passive devices 110, one or more IC chips 112, and interposer structure 114 can also be attached to substrate 104 using the surface-mount process. Other electrical component placement and routing techniques can also be used for one or more of these electrical components. Further, in some embodiments, opening 126 of electronic device 116 is covered with a tape or any other suitable covering material.

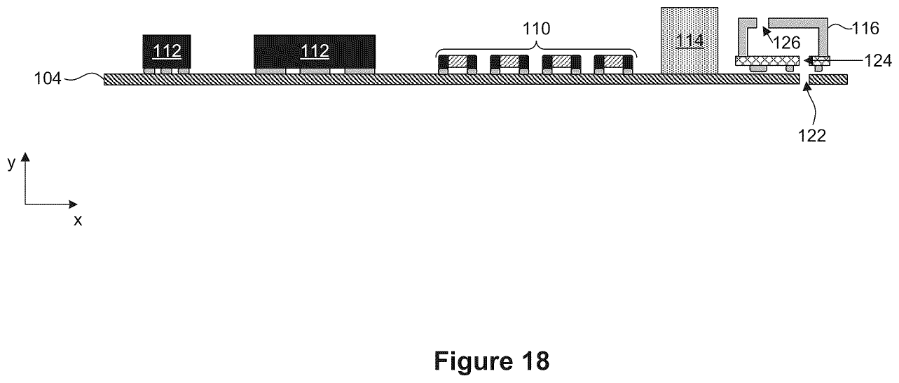

Referring to FIG. 18, for the manufacturing of electronic circuit package 100 without covering opening 126, electronic device 116 is attached to substrate 104 in a similar manner described above with respect to FIG. 17. But, unlike FIG. 17, opening 126 in FIG. 17 is not covered with a tape or any other suitable covering material.

Referring to FIG. 16, in operation 1620, a first molding compound layer is formed over the first surface of the substrate and to surround the electronic device. The first molding compound layer includes a fourth opening aligned with the third opening of the electronic device.

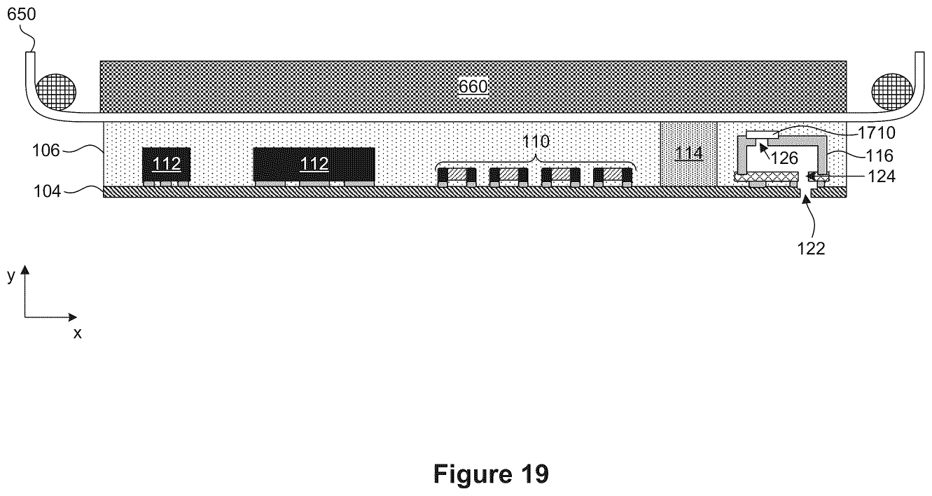

Referring to FIG. 19, for the manufacturing of electronic circuit package 100 while covering opening 126, a film-assisted molding process can be used to form molding compound layer 106 over the surface of substrate 104 and to surround electronic device 116. During the film-assisted molding process, film 650 can be positioned and vacuum sealed along a surface of chase 660 of a molding tool. After substrate 104 (with electrical components attached thereon) is transferred to the molding tool, film 650 is in contact with a surface (e.g., top surface) of interposer structure 114 so that, during a molding encapsulation process, molding compound layer 106 is formed around interposer structure 114 and surrounds the one or more passive devices 110, the one or more IC chips 112, and electronic device 116.

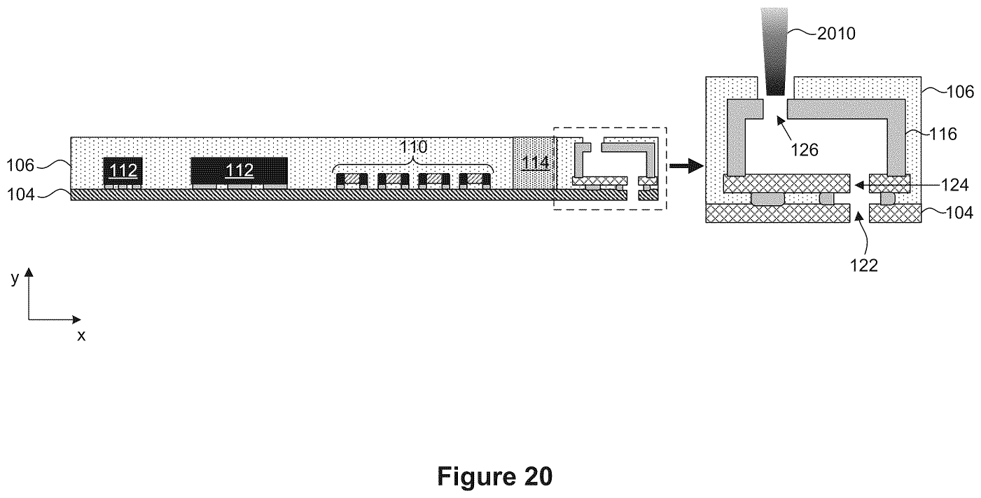

Referring to FIG. 20, for the manufacturing of electronic circuit package 100 while covering opening 126 and after substrate 104 (with electrical components attached thereon) is transferred out of the molding tool, opening 128 is formed. In some embodiments, a laser 2010 can irradiate a portion of molding compound layer 104 and the tape (or other suitable covering material) covering opening 126 to form opening 128, thus exposing opening 126 of electronic device 116. Other suitable techniques can be used to form opening 128.

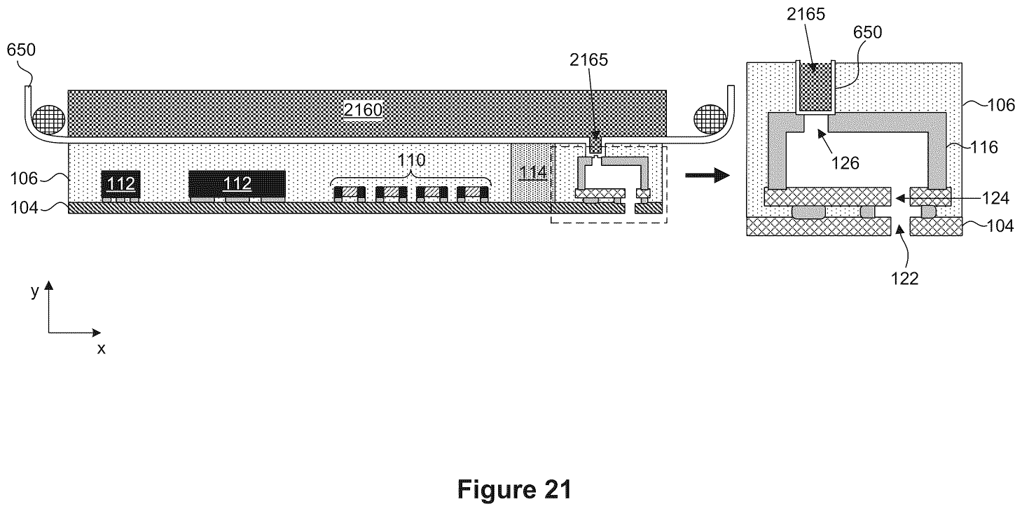

Referring to FIG. 21, for the manufacturing of electronic circuit package 100 without covering opening 126, a film-assisted molding process can be used to form molding compound layer 106 over the surface of substrate 104 and to surround electronic device 116. During the film-assisted molding process, film 650 can be positioned and vacuum sealed along a surface of chase 2160 of a molding tool. In some embodiments, chase 2160 can include an insert portion 2165 that lands on opening 126 of electronic device 116 during a molding encapsulation process. After substrate 104 (with electrical components attached thereon) is transferred to the molding tool, film 650 is in contact with a surface (e.g., top surface) of interposer structure 114 so that, during the molding encapsulation process, molding compound layer 106 is formed around insert portion 2165 and interposer structure 114 and also surrounds the one or more passive devices 110, the one or more IC chips 112, and electronic device 116. After operation 1620, opening 128 is formed in molding compound layer 106.

Referring to FIG. 16, in operation 1630, a second molding compound layer is formed over a second surface of the substrate. The second molding compound layer includes a fifth opening aligned with the first opening in the substrate and the second opening of the electronic device.

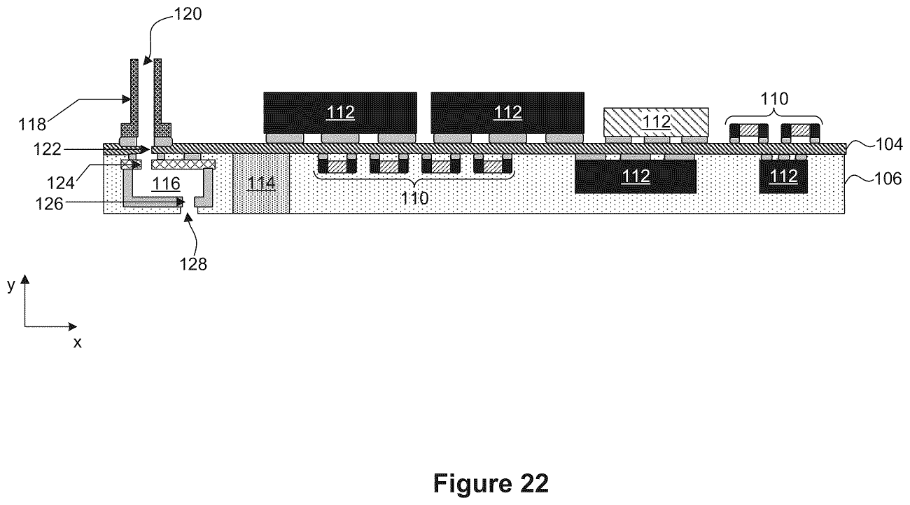

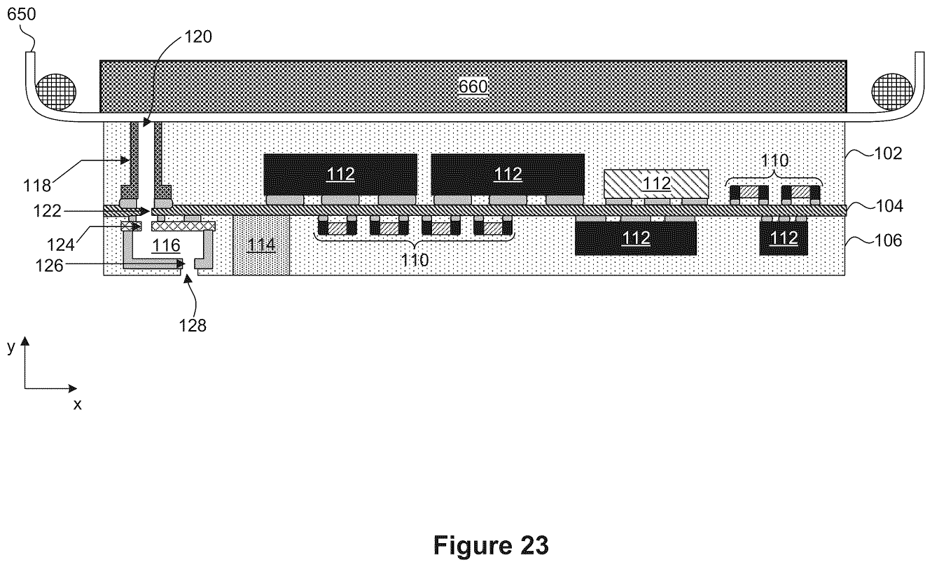

Referring to FIG. 22, prior to forming molding compound layer 102, guide structure 118, one or more passive devices 110, and one or more IC chips 112 can be attached to a surface of substrate 104 opposite to that of electronic device 116 in a similar manner as described above with respect to FIG. 7. Further, referring to FIG. 23, molding compound layer 102 is formed over the surface of substrate 104 with guide structure 118 in a similar manner as described above with respect to FIG. 8.

After molding compound layer 102 is formed, substrate 108 can be attached to molding compound layer 106. FIG. 1 shows the electronic circuit package with substrate 108, guide structure 118, and opening 120 in molding compound layer 102, according to some embodiments.

The present disclosure describes structures and methods directed to an electronic circuit package with a mold opening. For example, a structure can include a substrate with an opening, an electronic device disposed on a first surface of the substrate, and a molding compound layer disposed on a second surface of the substrate. The electronic device can include an opening aligned with the substrate's opening. Further, the molding compound layer can include an opening aligned with the electronic device and the substrate's openings. Depending on the type of operation of the electronic device (e.g., electronic sensor device), the electronic device can receive and/transmit signals—e.g., sound waves, optical signals, pressure signals, communication signals, and light-emitting signals—through the openings of the electronic device, substrate, and molding compound layer and process the signals accordingly.

Benefits of the above electronic circuit package, among others, include a miniaturized design with volumetric efficiency as compared to other electronic circuit packages with the electronic device and associated openings that deliver signals to the electronic device not in close proximity to one another. Another benefit of the above electronic circuit package is manufacturing simplicity, resulting in reduced manufacturing costs. For example, for the above electronic circuit package, the electronic device and molding compound layer can be manufactured on the same type of substrate—e.g., a rigid PCB—such that the manufacturing process does not need to be modified to integrate the electronic device on a different type of substrate—e.g., a flexible PCB—from other electronic components in the electronic system.

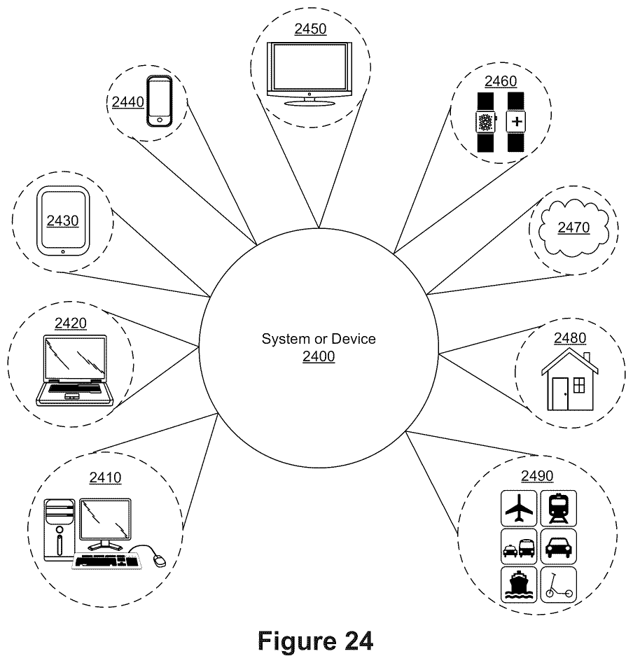

FIG. 24 is an illustration of exemplary systems or devices that can include the disclosed embodiments. System or device 2400 can incorporate one or more of the disclosed embodiments in a wide range of areas. For example, system or device 2400 can be implemented in one or more of a desktop computer 2410, a laptop computer 2420, a tablet computer 2430, a cellular or mobile phone 2440, and a television 2450 (or a set-top box in communication with a television).

Also, system or device 2400 can be implemented in a wearable device 2460, such as a smartwatch or a health-monitoring device. In some embodiments, the smartwatch can have different functions, such as access to email, cellular service, and calendar functions. Wearable device 2460 can also perform health-monitoring functions, such as monitoring a user's vital signs and performing epidemiological functions (e.g., contact tracing and providing communication to an emergency medical service). Wearable device 2460 can be worn on a user's neck, implantable in user's body, glasses or a helmet designed to provide computer-generated reality experiences (e.g., augmented and/or virtual reality), any other suitable wearable device, and combinations thereof.

Further, system or device 2400 can be implemented in a server computer system, such as a dedicated server or on shared hardware that implements a cloud-based service 2470. System or device 2400 can be implemented in other electronic devices, such as a home electronic device 2480 that includes a refrigerator, a thermostat, a security camera, and other suitable home electronic devices. The interconnection of such devices can be referred to as the “Internet of Things” (IoT). System or device 2400 can also be implemented in various modes of transportation 2490, such as part of a vehicle's control system, guidance system, and/or entertainment system. The systems and devices illustrated in FIG. 24 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate with a first surface and a second surface opposite to the first surface, wherein the substrate comprises a first opening (FIG. 1, 102);
an electronic device disposed on the first surface of the substrate, wherein the electronic device comprises a second opening aligned with the first opening of the substrate; and
a molding compound layer disposed on the second surface of the substrate, wherein the molding compound layer comprises a third opening aligned with the second opening of the electronic device.

2. The structure of claim 1, further comprising:
an other molding compound layer disposed on the first surface of the substrate, wherein the other molding compound layer comprises a fourth opening aligned with a fifth opening of the electronic device, and wherein the fifth opening is on an opposite surface of the electronic device to that of the second opening.

3. The structure of claim 2, further comprising:
an other substrate in contact with the other molding compound layer, wherein the other substrate comprises a sixth opening aligned with the fifth opening of the electronic device; and
an interposer structure disposed in the other molding compound layer and electrically connected to the substrate and the other substrate.

4. The structure of claim 1, further comprising:
a guide structure disposed along sidewalls of the third opening of the molding compound layer.

5. The structure of claim 4, wherein the guide structure comprises an L-shaped structure disposed on the second surface of the substrate.

6. The structure of claim 4, wherein the guide structure comprises a metallic barrier structure disposed on the second surface of the substrate.

7. The structure of claim 1, wherein the substrate comprises a printed circuit board.

8. The structure of claim 1, wherein the electronic device comprises a microphone device.

9. A structure, comprising:
a printed circuit board (PCB) with a first surface and a second surface opposite to the first surface, wherein the PCB comprises a PCB opening;
a first molding compound layer disposed on the first surface of the PCB, wherein the first molding compound layer comprises a sound guide opening aligned with the PCB opening;
a microphone device disposed on the second surface of the PCB, wherein the microphone device comprises a sound inlet opening aligned with the PCB opening and the sound guide opening; and
a second molding compound layer disposed on the second surface of the PCB and surrounding the microphone device.

10. The structure of claim 9, further comprising:
an L-shaped sound guide structure disposed along substantially vertical sidewalls of the sound guide opening.

11. The structure of claim 9, further comprising:
a metallic barrier layer disposed along angled sidewalls of the sound guide opening.

12. The structure of claim 9, wherein the microphone device further comprises:
a barometric relief vent on a surface of the microphone device opposite to that of the sound inlet opening.

13. The structure of claim 12, wherein the second molding compound layer comprises an opening aligned with the barometric relief vent.

14. The structure of claim 13, further comprising:
a flexible PCB in contact with the second molding compound layer, wherein the flexible PCB comprises an opening aligned with the opening of the second molding compound layer and the barometric relief vent.

15. A method, comprising:
attaching an electronic device to a first surface of a substrate and over a first opening in the substrate, wherein the electronic device comprises a second opening aligned with the first opening in the substrate;
forming a first molding compound layer over the first surface of the substrate and to surround the electronic device; and
forming, over a second surface of the substrate, a second molding compound layer with a third opening aligned with the first opening of the substrate and the second opening of the electronic device.

16. The method of claim 15, wherein attaching the electronic device comprises surface mounting the electronic device to the first surface of the substrate.

17. The method of claim 15, forming the first molding compound layer comprises:
attaching an interposer structure to the first surface of the substrate, wherein disposing the first molding compound layer comprises:
disposing a film in contact with the interposer structure; and
performing a molding encapsulation process around the interposer structure.

18. The method of claim 15, wherein forming the second molding compound layer comprises attaching a guide structure on the second surface of the substrate and over the first opening.

19. The method of claim 18, wherein forming the second molding compound layer comprises:
disposing a film over the guide structure; and
performing a molding encapsulation process around the guide structure to form the third opening.

20. The method of claim 15, wherein forming the second molding compound layer comprises:
landing an insert portion of a molding chase on the first opening in the substrate; and
performing a molding encapsulation process around the insert portion to form the third opening in the second molding compound layer.

21. A method, comprising:
attaching an electronic device to a first surface of a substrate and over a first opening in the substrate, wherein the electronic device comprises a second opening aligned with the first opening in the substrate and a third opening on a surface of the electronic device opposite to that of the second opening;
forming a first molding compound layer over the first surface of the substrate and to surround the electronic device, wherein the first molding compound layer comprises a fourth opening aligned with the third opening of the electronic device; and
forming, over a second surface of the substrate, a second molding compound layer with a fifth opening aligned with the first opening in the substrate and the second opening of the electronic device.

22. The method of claim 21, wherein attaching the electronic device comprises covering the third opening of the electronic device with a tape.

23. The method of claim 22, wherein disposing the first molding compound layer comprises forming the fourth opening through the first molding compound layer and the tape to expose the third opening of the electronic device.

24. The method of claim 23, wherein forming the fourth opening comprises irradiating, with a laser, a portion of the first molding compound layer and the tape to expose the third opening of the electronic device.

25. The method of claim 21, wherein forming the first molding compound layer comprises:
landing an insert portion of a molding chase on the third opening of the electronic device; and
performing a molding encapsulation process around the insert portion to form the fourth opening in the first molding compound layer.
